(19) United States
(12) Patent Application Publication
(10) Pub. No.: US 2026/0258197 A1
(43) Pub. Date: Sep. 3, 2026

(54) POLYPHENYLENE ETHER, CURABLE COMPOSITION CONTAINING POLYPHENYLENE ETHER, DRY FILM, PREPEG, CURED PRODUCT, AND ELECTRONIC COMPONENT

(71) Applicant: TAIYO HOLDINGS CO., LTD., Hiki-gun (JP)

(72) Inventors: Shoya SEKIGUCHI, Hiki-gun (JP); Shoko MISHIMA, Hiki-gun (JP); Yuki SUGITA, Hiki-gun (JP); Nobuhiro ISHIKAWA, Hiki-gun (JP)

(73) Assignee: TAIYO HOLDINGS CO., LTD., Hiki-gun (JP)

(21) Appl. No.: 19/489,490

(22) PCT Filed: Jun. 19, 2024
(86) PCT No.: PCT/JP2024/022202

§ 371 Date: Dec. 2, 2025

(30) Foreign Application Priority Data
Jun. 29, 2023 (JP) 2023-107451

(51) Int. Cl. C08G 65/44; C08J 5/18

(52) U.S. Cl. CPC C08G 65/44; C08J 5/18; C08J 2371/12

(57) ABSTRACT

A polyphenylene ether having a branched structure, the polyphenylene ether having low-dielectric characteristics and excellent solvent solubility, being easily controlled in molecular weight, and being suitable for mass production. The polyphenylene ether is obtained from raw material phenols, in which the raw material phenols include a phenol having a hydrogen atom at the ortho position and the para position and a phenol (X) represented by formula (1)

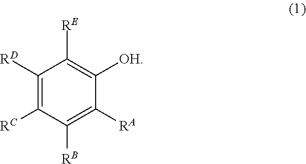

### TECHNICAL FIELD

The present invention relates to a polyphenylene ether, a curable composition containing polyphenylene ether, a dry film, a cured product, and an electronic component.

### BACKGROUND ART

With the spread of large-capacity high-speed communication typified by a fifth generation communication system (5G), millimeter wave radars for an advanced driving assistant system (ADAS) of automobiles, and the like, the higher frequency of signals on communication devices has been progressed.

However, when an epoxy resin or the like is used as the wiring board material, the relative permittivity (Dk) and the dielectric loss tangent (Df) are not sufficiently low, and therefore the transmission loss derived from the dielectric loss increases as the frequency increases, causing problems such as signal attenuation and heat generation. Therefore, polyphenylene ethers excellent in low dielectric properties have been used.

In addition, Non Patent Literature 1 has proposed a polyphenylene ether having heat resistance improved by introducing an allyl group into a molecule of the polyphenylene ether to form a thermosetting resin.

However, the soluble solvent of polyphenylene ether is limited, and the polyphenylene ether obtained by the method of Non Patent Literature 1 also dissolves only in a highly toxic solvent such as chloroform and toluene. Therefore, there is a problem in that it is difficult to handle a resin varnish and to manage solvent exposure in a step of forming a coating film for a wiring board and curing the coating film.

### CITATION LIST

### Non Patent Literature

Non Patent Literature 1: J. Nunoshige, H. Akahoshi, Y Shibasaki, M. Ueda, J. Polym. Sci. Part A: Polym. Chem. 2008, 46, 5278-5282.

### SUMMARY OF INVENTION

### Technical Problem

Under such circumstances, the present inventors have found that a polyphenylene ether having a branched structure synthesized using a specific phenol as a raw material has high solvent solubility (JP 2020-015909 A).

However, the present inventors have further studied and newly found that since the polyphenylene ether having a branched structure has a larger number of polymer terminals having polymerization reactivity than a polyphenylene ether having a linear structure, there is a problem in that the grown polymers undergo further polymerization (so-called coupled) resulting in a rapid increase in the molecular weight. Therefore, in order to control the molecular weight of a polyphenylene ether to be obtained within a desired range, selection of raw materials, fine adjustment of production conditions, and the like are required, and there are cases where the polyphenylene ether is not suitable for mass production.

The present inventors have newly found that a low-molecular-weight polyphenylene ether synthesized by controlling the molecular weight may deteriorate film physical properties, such as mechanical strength in a case where the polyphenylene ether is formed into a cured product, due to a low molecular weight.

Therefore, an object of the present invention is to provide a polyphenylene ether having a branched structure, the polyphenylene ether being easily controlled in molecular weight and also being excellent in mechanical strength of a cured product while suppressing an increase in molecular weight.

### Solution to Problem

The present inventors have conducted intensive studies, and have found that the above problems can be solved by a polyphenylene ether obtained from raw material phenols including a phenol having a specific structure. That is, the present invention is as follows.

An embodiment of the present invention is a polyphenylene ether.

The polyphenylene ether is obtained from raw material phenols, in which the raw material phenols include a phenol satisfying at least the following Condition 1 and a phenol (X) represented by the following Formula (1).

### (Condition 1)

### Including a Hydrogen Atom at the Ortho Position and the Para Position

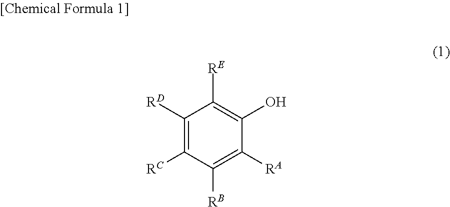

wherein, in Formula (1), R^{A}, R^{C}, and R^{E} are each independently a functional group having 1 to 10 carbon atoms, R^{B} and R^{D} are each independently hydrogen or a functional group having 1 to 10 carbon atoms, and one or more of R^{A} to R^{E} are a functional group containing an unsaturated carbon bond.

The phenol (X) is preferably a compound represented by the following Formula (2) or (3).

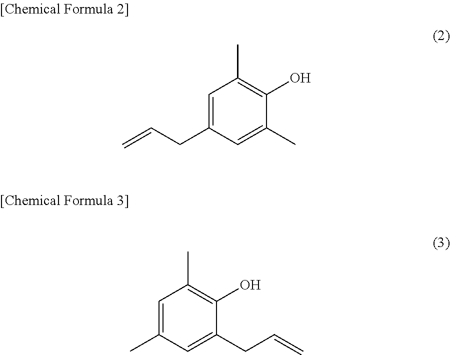

Another embodiment of the present invention is a curable composition containing the above-described polyphenylene ether.

Still another embodiment of the present invention is a dry film or prepreg obtained by applying or impregnating the above-described curable composition to a base material.

Still another embodiment of the present invention is a cured product obtained by curing the above-described curable composition.

Still another embodiment of the present invention is a laminate including the above-described cured product.

Still another embodiment of the present invention is an electronic component including the above-described cured product.

### Advantageous Effects of Invention

According to the present invention, it is possible to provide a polyphenylene ether having a branched structure, the polyphenylene ether being easily controlled in molecular weight and also being excellent in mechanical strength of a cured product while suppressing an increase in molecular weight.

### BRIEF DESCRIPTION OF DRAWINGS

FIG. 1 shows a ¹H-NMR (CDCl₃, room temperature) spectrum of a polyphenylene ether according to Example 1.

FIG. 2 shows a ¹H-NMR (CDCl₃, room temperature) spectrum of a polyphenylene ether according to Example 2.

### DESCRIPTION OF EMBODIMENTS

In a case where the compounds described have isomers, unless otherwise specified, all isomers that may be present can be used in the present invention.

In the present specification, the term “unsaturated carbon bond” indicates an ethylenic or acetylenic carbon-carbon multiple bond (a double bond or a triple bond) unless otherwise specified.

In the present specification, the functional group containing an unsaturated carbon bond is not particularly limited, but examples thereof include an alkenyl group (for example, a vinyl group or an allyl group), an alkynyl group (for example, an ethynyl group), and a (meth)acryloyl group, and from the viewpoint of having excellent curability, a vinyl group, an allyl group, or a (meth)acryloyl group can be selected, and among them, from the viewpoint of having excellent low-dielectric characteristics, an allyl group is preferable. Note that the number of carbon atoms of these functional groups containing an unsaturated carbon bond can be set, for example, to 15 or less, 10 or less, 8 or less, 5 or less, 3 or less, or the like.

In the present specification, the hydrocarbon group is not particularly limited, but means a group composed only of a carbon atom and a hydrogen atom, and examples thereof include an alkyl group, an alkenyl group, an alkynyl group, an aryl group, and a cycloalkyl group.

In the present specification, phenols that are used as raw materials of a polyphenylene ether (PPE) and can serve as constitutional units of the polyphenylene ether are collectively referred to as “raw material phenols”.

In the present specification, in the case of expressing the “ortho position”, the “para position”, and the like when raw material phenols are described, unless otherwise specified, these expressions are based on the position of a phenolic hydroxyl group (ipso position).

In the present specification, the case of simply expressing the “ortho position” and the like indicates “at least one of the ortho positions” and the like. Therefore, in the case of simply expressing the “ortho position”, it may be interpreted that it indicates any one of the ortho positions and both the ortho positions as long as inconsistency does not occur.

In the present specification, the number average molecular weight (Mn) and the weight average molecular weight (Mw) of the polyphenylene ether are determined by gel permeation chromatography (GPC). In GPC, Shodex K-805L is used as a column, the column temperature is set to 40° C., the flow rate is set to 1 mL/min, chloroform is used as an eluent, and polystyrene is used as a standard substance.

In the present specification, the case of separately describing an upper limit value and a lower limit value in a numerical range means that all combinations of each lower limit value and each upper limit value that do not conflict with each other are substantively described.

Hereinafter, a polyphenylene ether, a curable composition containing the polyphenylene ether, and a dry film, a cured product, and an electronic component which are obtained by using the curable composition will be described.

### <<<Polyphenylene Ether>>>

### <<Raw Material Phenols>>

Raw material phenols of a polyphenylene ether according to the present embodiment include a phenol satisfying at least the following Condition 1 and a predetermined phenol (X).

### (Condition 1)

### Including a Hydrogen Atom at the Ortho Position and the Para Position

The raw material phenols may include other phenols.

Hereinafter, each phenol will be described.

Although monovalent phenols are mainly disclosed as the raw material phenols described below, polyvalent phenols may be used as the raw material phenols as long as the effect of the present disclosure is not inhibited.

### <Phenol Satisfying at Least Condition 1>

The phenol satisfying at least Condition 1 has a hydrogen atom in ortho and para positions.

The phenol satisfying at least Condition 1 may further satisfy the following Condition 2.

### (Condition 2)

### Including a Hydrogen Atom at the Para Position, and Including a Functional Group Including an Unsaturated Carbon Bond

That is, the phenol satisfying at least Condition 1 may be any of (1) a phenol satisfying only Condition 1 but not satisfying Condition 2 and (2) a phenol satisfying both Condition 1 and Condition 2, and the raw material phenols may include both of these phenols.

Since the phenol satisfying Condition 1 has a hydrogen atom in the ortho position, at the time of oxidation polymerization with other phenols, an ether bond can be formed not only in the ipso position and the para position but also in the ortho position, and thus a polyphenylene ether obtained using such a phenol as a raw material phenol can form a branched chain structure.

More specifically, in a polyphenylene ether obtained from raw material phenols including a phenol satisfying Condition 1, a part of the structure thereof is branched by a benzene ring ether-bonded at least at three positions of the ipso position, the ortho position, and the para position.

As described above, the polyphenylene ether having a branched structure in the skeleton may be referred to as a branched polyphenylene ether. According to the branched polyphenylene ether, excellent solubility in an organic solvent can be obtained.

Since the phenol satisfying Condition 2 has a functional group containing an unsaturated carbon bond, a polyphenylene ether obtained using such a phenol as a raw material phenol has a functional group containing an ethylenic or acetylenic carbon-carbon multiple bond.

More specifically, in a polyphenylene ether obtained from raw material phenols including a phenol satisfying Condition 2, a part of the structure thereof has a functional group containing an unsaturated carbon bond in at least one of a meta position and two ortho positions of a benzene ring.

Examples of the phenol satisfying only Condition 1 but not satisfying Condition 2 include phenol, o-cresol, m-cresol, o-ethylphenol, m-ethylphenol, 2,3-xylenol, 2,5-xylenol, 3,5-xylenol, o-tert-butylphenol, m-tert-butylphenol, o-phenylphenol, m-phenylphenol, and 2-dodecylphenol. As the phenol satisfying Condition 1, only one kind or two or more kinds may be used.

Examples of the phenol satisfying both Condition 1 and Condition 2 include o-vinylphenol, m-vinylphenol, o-allylphenol, m-allylphenol, 3-vinyl-6-methylphenol, 3-vinyl-6-ethylphenol, 3-vinyl-5-methylphenol, 3-vinyl-5-ethylphenol, 3-allyl-6-methylphenol, 3-allyl-6-ethylphenol, 3-allyl-5-methylphenol, and 3-allyl-5-ethylphenol. As the phenol satisfying Condition 1 and Condition 2, only one kind or two or more kinds may be used.

In the synthesis of the polyphenylene ether, the content ratio of the phenol (A) satisfying at least Condition 1 to the total amount of the raw material phenols is preferably 1 mol % or more, 2 mol % or more, 3 mol % or more, or 5 mol % or more, and is preferably 50 mol % or less, 40 mol % or less, 30 mol % or less, 20 mol % or less, or 15 mol % or less.

### <Phenol (X)>

The phenol (X) has a structure represented by the following Formula (1).

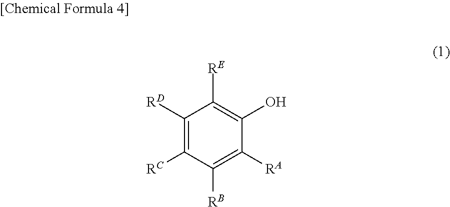

In Formula (1), R^{A}, R^{C}, and R^{E} are each independently a functional group having 1 to 10 carbon atoms, R^{B} and R^{D} are each independently hydrogen or a functional group having 1 to 10 carbon atoms, and one or more of R^{A} to R^{E} are a functional group containing an unsaturated carbon bond.

The phenol compound (X) may have one or two or more functional groups containing an unsaturated carbon bond.

As described above, the polyphenylene ether according to the present embodiment has a branched structure by containing the phenol satisfying Condition 1 as a raw material phenol.

Since the polyphenylene ether having a branched structure has a larger number of polymer terminals having polymerization reactivity than a polyphenylene ether having a linear structure, the grown polymers may be further subjected to polymerization (so-called coupling) to rapidly increase the molecular weight, and it is not easy to control the reaction.

Based on such findings, in the present embodiment, as raw material phenols, the phenol (X) was further combined in addition to the phenol satisfying Condition 1.

Since the phenol (X) does not have a hydrogen atom in the highly reactive ortho and para positions, the polymerization reaction is stopped at the end of the polyphenylene ether molecular chain to which the phenol (X) has reacted. Therefore, when the phenol (X) moderately constitutes the terminal portion of the polyphenylene ether, a rapid increase in molecular weight (coupling reaction) occurring in the synthesis of the polyphenylene ether having a branched structure can be suppressed. The polyphenylene ether thus obtained is likely to be excellent in storage stability because an unintended increase in molecular weight is suppressed.

For example, as in U.S. Pat. No. 3,440,217, a method of controlling the molecular weight of a polyphenylene ether having a linear structure using a tri-substituted phenol such as 2,6-dimethylphenol or 2,4,6-trimethylphenol as a raw material phenol is known. However, in the linear polyphenylene ether, since the polymerization reaction proceeds only at one terminal of the polyphenylene ether molecular chain, the polymerization reaction is stopped when the tri-substituted phenol is reacted. Therefore, the present inventors have found that in a polyphenylene ether having a linear structure in which the molecular weight is controlled using a tri-substituted phenol, the molecular weight of the polyphenylene ether is extremely low, and the mechanical strength may be significantly reduced. In this regard, in the present embodiment, it has been found that by using the phenol (X) as a raw material phenol of the polyphenylene ether having a branched structure, an effect by which a polyphenylene ether having a desired molecular weight range without excessively suppressing an increase in molecular weight can be obtained is further exhibited. In the polyphenylene ether having a branched structure, polymerization proceeds at two or more reactive terminals, and thus, even when the phenol (X) reacts, polymerization can be performed at another reactive terminal, and an increase in molecular weight is not excessively suppressed, so that it is presumed that a polyphenylene ether having a desired molecular weight range can be obtained.

As a result, the reaction can be easily controlled, and a polyphenylene ether having a desired molecular weight range (particularly, a polyphenylene ether having a weight average molecular weight of 5,000 to 300,000 which is industrially useful) can be efficiently produced while maintaining excellent performance (low-dielectric characteristics, excellent solvent solubility) derived from a branched structure. Such a polyphenylene ether is also excellent in the mechanical strength of a cured product while controlling the molecular weight.

The phenol (X) has a functional group containing at least an unsaturated carbon bond. In other words, the polyphenylene ether having a branched structure obtained using the phenol (X) has a functional group containing at least an unsaturated carbon bond (derived from the phenol (X)), and exhibits crosslinkability. As described above, since the phenol (X) moderately constitutes the terminal portion of the polyphenylene ether, a the obtained polyphenylene ether having a branched structure exhibits crosslinkability at the terminal portion of the branched structure, and the crosslinking reactivity of the polyphenylene ether is easily improved while excellent solvent solubility is maintained (or the mechanical strength of a cured product to be obtained is easily improved).

It is presumed that a polyphenylene ether having excellent mechanical strength of a cured product while controlling the molecular weight can be obtained by such a synergistic effect of each configuration according to the present embodiment.

The functional group containing an unsaturated carbon bond contained in the phenol (X) is preferably a functional group containing an unsaturated double bond and having 3 or more carbon atoms. When the number of carbon atoms of the functional group containing an unsaturated double bond is 3 or more, easiness of production, storage stability, and the like are excellent.

From the viewpoint of further enhancing the effect according to the present disclosure, the phenol (X) is preferably as follows.

In Formula (1), the functional group containing an unsaturated carbon bond is preferably a hydrocarbon group. In a case where the functional group containing an unsaturated carbon bond is a hydrocarbon group, the number of carbon atoms is preferably 3 to 10, 3 to 5, or 3. More specifically, the hydrocarbon group containing an unsaturated carbon bond is preferably a group represented by [—(CH₂)ₙ—CH═CH₂] (n is an integer of 1 to 8). n is more preferably an integer of 1 to 3 and particularly preferably 1.

In Formula (1), R^{A}, R^{C}, and R^{E} are each independently preferably a hydrocarbon group having 10 or less carbon atoms, 5 or less carbon atoms, or 3 or less carbon atoms.

In Formula (1), one or more of R^{A}, R^{C}, and R^{E} are preferably a functional group containing an unsaturated carbon bond. More specifically, in Formula (1), it is preferable that any one of R^{A}, R^{C}, and R^{E} is a functional group containing an unsaturated carbon bond, and the others are functional groups not containing an unsaturated carbon bond.

In Formula (1), it is preferable that at least R^{C} is a functional group containing an unsaturated carbon bond from the viewpoint that a cured product particularly excellent in elongation at break can be obtained. Since the functional group containing an unsaturated carbon bond in the para position has higher crosslinking reactivity than the functional group containing an unsaturated carbon bond in the ortho position or the meta position, it is presumed that a polyphenylene ether having particularly excellent mechanical strength of a cured product can be obtained. In Formula (1), it is preferable that at least any one of R^{A} and R^{E} is a functional group containing an unsaturated carbon bond from the viewpoint that a cured product having a particularly high elastic modulus can be obtained.

In Formula (1), R^{B} and R^{D} are each independently preferably hydrogen or a hydrocarbon group having 10 or less carbon atoms, hydrogen or a hydrocarbon group having 5 or less carbon atoms, hydrogen or a hydrocarbon group having 3 or less carbon atoms, hydrogen or a hydrocarbon group having 1 carbon atom, or hydrogen.

In Formula (1), in a case where R^{B} and R^{D} are a hydrocarbon group, they are preferably a hydrocarbon group not containing an unsaturated carbon bond.

In Formula (1), as described above, one or more of R^{A} to R^{E} are a functional group containing an unsaturated carbon bond. In this case, in R^{A} to R^{E}, a substituent other than hydrogen that does not correspond to the functional group containing an unsaturated carbon bond is preferably a hydrocarbon group having 1 to 10, 1 to 5, or 1 to 3 carbon atoms.

Specific examples of the phenol (X) include a compound represented by the following Formula (2) (4-allyl-2,6-dimethylphenol) and a compound represented by the following Formula (3) (2-allyl-4,6-dimethylphenol). The phenol (X) can be produced using a known method such as a synthesis method described in WO 2021/070714.

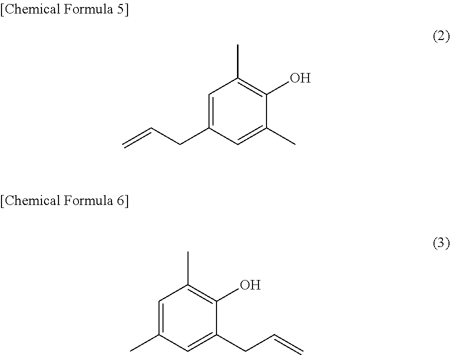

In the synthesis of the polyphenylene ether, the content ratio of the phenol (X) to the total amount of the raw material phenols is preferably 1 mol % or more, 2 mol % or more, 3 mol % or more, or 5 mol % or more, and is preferably 50 mol % or less, 40 mol % or less, 30 mol % or less, 20 mol % or less, or 15 mol % or less.

The ratio of the content ratio (mol %) of the phenol (X) to the content ratio (mol %) of the phenol satisfying Condition 1 (phenol (X)/phenol satisfying Condition 1) based on the total amount of the raw material phenols is preferably 0.1 to 10.0, 0.2 to 5.0, or 0.5 to 2.0.

### <Other Phenols>

Other phenols are phenols not satisfying Condition 1 and not corresponding to the phenol (X).

Examples of the other phenols include (1) a phenol not satisfying Condition 1 but satisfying Condition 2, and not corresponding to the phenol (X), and (2) a phenol not satisfying both Condition 1 and Condition 2 and not corresponding to the phenol (X).

The phenol not satisfying Condition 1 but satisfying Condition 2, and not corresponding to the phenol (X) is, for example, a phenol having a hydrogen atom in the para position, having hydrocarbon groups in both ortho positions, in which at least one of the hydrocarbon groups has an unsaturated carbon bond. Examples of such a phenol include 2-allyl-6-methylphenol, 2-allyl-6-ethylphenol, 2-allyl-6-phenylphenol, 2-allyl-6-styrylphenol, 2,6-divinylphenol, 2,6-diallylphenol, 2,6-diisopropenylphenol, 2,6-dibutenylphenol, 2,6-diisobutenylphenol, 2,6-diisopentenylphenol, 2-methyl-6-styrylphenol, 2-vinyl-6-methylphenol, and 2-vinyl-6-ethylphenol.

The phenol not satisfying both Condition 1 and Condition 2 and not corresponding to the phenol (X) is, for example, a phenol having a hydrogen atom in the para position and having a functional group not containing an unsaturated carbon bond in any ortho positions. Examples of such a phenol include 2,6-dimethylphenol, 2,3,6-trimethylphenol, 2-methyl-6-ethylphenol, 2-ethyl-6-n-propylphenol, 2-methyl-6-n-butylphenol, 2-methyl-6-phenylphenol, 2,6-diphenylphenol, and 2,6-ditolylphenol.

As described above, in the case of using a phenol having a hydrogen atom in the para position as the other phenol, an ether bond is formed at the ipso and para-positions of the benzene ring, and the phenol is polymerized in a linear form, so that it is useful for adjusting the ratio of the branched structure, and the molecular weight of the polyphenylene ether is easily adjusted.

Examples of the phenol not satisfying both Condition 1 and Condition 2 and not corresponding to the phenol (X) include a phenol not having a hydrogen atom in the para and ortho positions and not having a functional group containing an unsaturated carbon bond.

As described above, in the case of using a phenol not having a hydrogen atom in either the para position or the ortho position as the other phenol, the polymerization reaction of the polyphenylene ether is suppressed, and the molecular weight of the polyphenylene ether is easily adjusted.

Only one kind of the other phenols may be used, or two or more kinds thereof may be used.

In the synthesis of the polyphenylene ether, in the case of using the other phenols, the content ratio of the other phenols to the total amount of the raw material phenols is, for example, 10 mol % or more, 20 mol % or more, 30 mol % or more, 40 mol % or more, or 50 mol % or more.

### <<Method for Producing Polyphenylene Ether>>

The polyphenylene ether of the present disclosure can be produced by a known method for synthesizing a polyphenylene ether except that the raw material phenols to be used and the ratio of the raw material phenols are as described above. For example, the polyphenylene ether can be produced by a synthesis method disclosed in WO 2020/017570.

### <<Physical Properties/Properties of Polyphenylene Ether>>

The weight average molecular weight of the polyphenylene ether is preferably 5,000 to 40,000, more preferably 8,000 to 30,000, and more preferably 10,000 to 25,000.

The number average molecular weight of the polyphenylene ether is preferably 5,000 to 20,000 and more preferably 5,000 to 10,000.

The molecular weight of the polyphenylene ether can be adjusted by changing the reaction temperature, the reaction time, and the like at the time of synthesis, although depending on the type of the raw material phenols to be used. By increasing the ratio of the phenol (X) in the raw material phenols and the ratio of the phenol not having a hydrogen atom in the para and ortho positions among the other phenols, the polymerization reaction is suppressed, the rate of molecular weight increase is slowed, and the molecular weight of the polyphenylene ether is easily controlled.

### <<<Curable Composition>>>

A curable composition comprises the polyphenylene ether according to the present embodiment.

The curable composition may contain other components.

The content of the polyphenylene ether in the curable composition is preferably 40 to 90 mass % and more preferably 50 to 80 mass % based on the total amount excluding a volatile component and an inorganic filler in the curable composition.

Examples of the other components include an inorganic filler such as silica, a peroxide, a crosslinking curing agent, a polyphenylene ether other than the polyphenylene ether according to the present embodiment, a polymerization initiator, resin and polymer components such as a maleimide resin and a styrene-based elastomer, and additives such as a sensitizer, an adhesion aid, a surfactant, a leveling agent, a plasticizer, an adhesive, a colorant, fibers, a silane coupling agent, a flame retardant, cellulose nanofibers, a dispersant, a thermosetting catalyst, a thickener, an antifoaming agent, an antioxidant, a rust inhibitor, and an adhesion imparting agent.

The other components may be appropriately selected according to the use application and the like. As an example, in a case where the curable composition contains a peroxide, the crosslinking reaction of the curable composition is accelerated, and various physical properties of the cured product are easily improved. In a case where the curable composition contains a crosslinking curing agent, the low-dielectric characteristics, heat resistance, and the like of the cured product are easily improved.

Examples of the peroxide include methyl ethyl ketone peroxide, methyl acetoacetate peroxide, acetylaceto peroxide, 1,1-bis(t-butylperoxy)cyclohexane, 2,2-bis(t-butylperoxy)butane, t-butyl hydroperoxide, cumene hydroperoxide, diisopropylbenzene hydroperoxide, 2,5-dimethylhexane-2,5-dihydroperoxide, 1,1,3,3-tetramethylbutyl hydroperoxide, di-t-butyl hydroperoxide, t-butyl hydroperoxide, dicumyl peroxide, 2,5-dimethyl-2,5-di(t-butylperoxy)hexane, 2,5-dimethyl-2,5-di(t-butylperoxy)hexyne, 2,5-dimethyl-2,5-di(t-butylperoxy)-3-butene, acetyl peroxide, octanoyl peroxide, lauroyl peroxide, benzoyl peroxide, m-toluyl peroxide, diisopropyl peroxydicarbonate, t-butylene peroxybenzoate, di-t-butyl peroxide, t-butylperoxy isopropyl monocarbonate, and α,α′-bis(t-butylperoxy-m-isopropyl)benzene. Only one kind of the peroxide may be used, or two or more kinds thereof may be used.

In a case where the content of the polyphenylene ether in the curable composition is 100 parts by mass, the content of the peroxide in the curable composition is preferably 0.1 to 10 parts by mass and more preferably 1 to 5 parts by mass.

Examples of the crosslinking curing agent include polyfunctional vinyl compounds such as divinylbenzene, divinylnaphthalene, and divinylbiphenyl; vinylbenzyl ether-based compounds synthesized from reaction of phenol and vinylbenzyl chloride; a styrene monomer such as diallyl phthalate or diallyl isophthalate, allyl ether-based compounds synthesized from reaction of a phenol and allyl chlorid; and trialkenyl isocyanurates such as triallyl isocyanurate (hereinafter, TAIC (registered trademark)) and triallyl cyanurate. Among them, triallyl isocyanurate, triallyl cyanurate, diallyl phthalate, and diallyl isophthalate, which have particularly favorable compatibility with the polyphenylene ether, are preferable. Only one kind of the crosslinking curing agent may be used, or two or more kinds thereof may be used.

In a case where the content of the polyphenylene ether in the curable composition is 100 parts by mass, the content of the crosslinking curing agent in the curable composition is preferably 1 to 100 parts by mass and more preferably 10 to 80 parts by mass.

The curable composition may be in the form of a varnish containing a solvent.

As the solvent, a solvent capable of dissolving the polyphenylene ether described above is preferable, and for example, in addition to a conventionally usable solvent such as chloroform, methylene chloride, or toluene, N-methyl-2-pyrrolidone (NMP), tetrahydrofuran (THF), cyclohexanone, propylene glycol monomethyl ether acetate (PMA), diethylene glycol monoethyl ether acetate (CA), methyl ethyl ketone, ethyl acetate, and the like are preferably used. Only one kind of them may be used, or two or more kinds thereof may be used.

### <<<Dry Film and Prepreg>>>

A dry film has a resin layer formed of the curable composition of the present disclosure on a carrier film (support film). The dry film is used by laminating a resin layer so as to be in contact with a base material.

The dry film can be produced by uniformly applying a curable composition onto a carrier film by an appropriate method such as a blade coater, a lip coater, a comma coater, or a film coater, and drying the composition to form the resin layer described above, and preferably stacking a cover film (protective film) thereon. The cover film and the carrier film may be the same film material or different films.

As the film material of the carrier film and the cover film, any of film materials known as film materials used for the dry film can be used.

As the carrier film, for example, a thermoplastic film such as a polyester film, such as polyethylene terephthalate having a thickness of 2 to 150 μm, is used.

As the cover film, a polyethylene film, a polypropylene film, or the like can be used, but it is preferable that the adhesive force of a film to the resin layer is smaller than that of the carrier film.

The film thickness of the resin layer on the dry film is preferably 100 μm or less, and more preferably in a range of 5 to 50 μm.

The prepreg is obtained, for example, by impregnating a base material such as glass cloth with the curable composition and drying the base material.

### <<<Cured Product>>>

A cured product can be produced using the curable composition or the dry film having a resin layer formed of the curable composition.

A method for obtaining a cured product from the curable composition is not particularly limited, and can be appropriately changed according to the composition of the curable composition.

For example, a cured product can be formed by the following method.

After the curable composition is applied onto the base material as described above (for example, coating by an applicator or the like), a drying step of drying the curable composition is performed as necessary to form a resin layer on the base material. Alternatively, the dry film is laminated on a base material to transfer a resin layer formed of the curable composition.

Next, a thermal curing step of thermally crosslinking the polyphenylene ether by heating (for example, heating by an inert gas oven, a hot plate, a vacuum oven, a vacuum press machine, or the like) is performed to cure the resin layer.

The conditions for carrying out each step (for example, coating thickness, drying temperature and time, heating temperature and time, and the like) may be appropriately changed according to the composition, use application, and the like of the curable composition.

### <<<Electronic Component>>>

An electronic component has the cured product of the present disclosure described above, and the cured product of the present disclosure has excellent dielectric characteristics, heat resistance, and mechanical strength, and thus can be used for various use applications as a material constituting a laminate or an electronic component.

The application thereof is not particularly limited, but preferred examples include insulating materials for electronic components such as millimeter-wave radars and the like for high-capacity and high-speed communication typified by the 5th generation communication system (5G) or advanced driver assistance system (ADAS) for automobiles.

### EXAMPLES

### <<Synthesis of Polyphenylene Ether>>

### Example 1

As the raw material phenols, 2,6-dimethylphenol, 2-allylphenol, and 4-allyl- 2,6-dimethylphenol were used.

Using a 500 mL separable flask as a reaction vessel, 34.51 g (80 mol %) of 2,6-dimethylphenol, 4.71 g (10 mol %) of 2-allylphenol, and 5.70 g (10 mol %) of 4-allyl-2,6-dimethylphenol were dissolved in 286.30 g of toluene to prepare a raw material solution. The amounts of di-p-hydroxo-bis[(N,N,N′,N′-tetramethylethylenediamine) copper(II)]chloride (Cu/TMEDA) and tetramethylethylenediamine (TMEDA) were adjusted to 1.04 g and 1.06 g, respectively, and the mixture was stirred at a stirring speed of 200 rpm and reacted at 40° C. for 15 hours while blowing dry air into the reaction solution at a flow rate of 150 mL/min to obtain a reaction solution containing a polyphenylene ether.

After stopping the heating of the reaction solution and blowing of dry air, di-μ-hydroxo-bis[(N,N,N′,N′-tetramethylethylenediamine) copper(II)]chloride (Cu/TMEDA) was removed by filtration, reprecipitated using a mixed solution of 1,200 mL of methanol, 4.0 mL of concentrated hydrochloric acid and 27.0 mL of H₂O, taken out by reduced pressure filtration, washed with methanol, and then dried at 80° C. for 24 hours to obtain a polyphenylene ether according to Example 1.

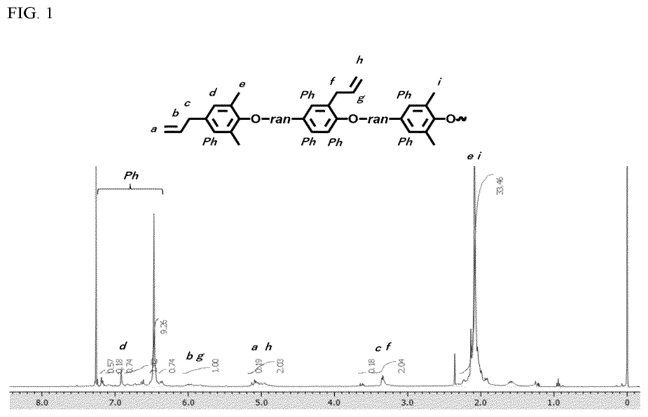

FIG. 1 shows a ¹H-NMR (CDCl₃, room temperature) spectrum of a polyphenylene ether according to Example 1.

### Example 2

A polyphenylene ether according to Example 2 was obtained in the same manner as in Example 1 except that 2,6-dimethylphenol, 2-allylphenol, and 2-allyl-4,6-dimethylphenol were used as the raw material phenols and the production conditions shown in Table 1 were employed.

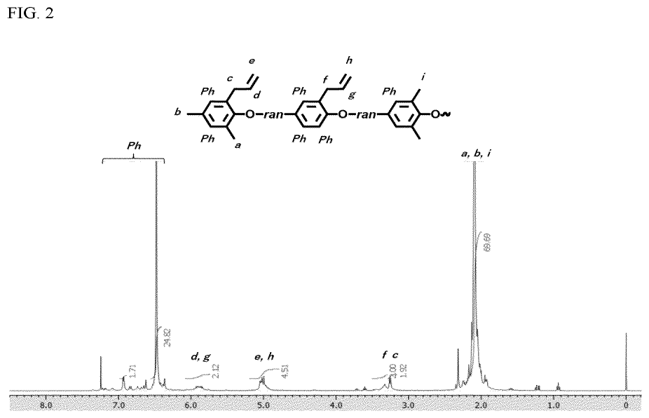

FIG. 2 shows a ¹H-NMR (CDCl₃, room temperature) spectrum of a polyphenylene ether according to Example 2.

### Comparative Example 1

A polyphenylene ether according to Comparative Example 1 was obtained in the same manner as in Example 1 except that 2,6-dimethylphenol, 2-allylphenol, and 2,4,6-trimethylphenol were used as the raw material phenols and the production conditions shown in Table 1 were employed.

### Reference Example 1

A polyphenylene ether according to Reference Example 1 was obtained in the same manner as in Example 1 except that 2,6-dimethylphenol and 2-allylphenol were used as the raw material phenols and the production conditions shown in Table 1 were employed.

### <Molecular Weight>

The weight average molecular weight and the number average molecular weight of the polyphenylene ethers of Example 1, Example 2, Comparative Example 1, and Reference Example 1 were measured. The measurement results are shown in Table 1.

### <Number of Terminal Reactive Groups Per Number Average Molecular Weight>

First, the polymerization ratio of each raw material phenol is calculated from the result of ¹H-NMR measurement for each sample, and the theoretical value of the functional group equivalent is calculated from the polymerization ratio X of the repeating structure derived from each raw material phenol in a case where the structure derived from the phenol compound X is 1, according to the following formula.

$$Functional group equivalent = Molecular weight of terminal structure derived from phenol compound X + {\sum }_{i} {X}_{i} {W}_{i}$$

Here, Xᵢ represents the polymerization ratio of the raw material phenol i, and Wᵢ represents the molecular weight of the repeating unit structure derived from the raw material phenol i. The number of terminal reactive groups per number average molecular weight was calculated by dividing the number average molecular weight obtained by GPC measurement by the functional group equivalent obtained by the above formula. The number of terminal reactive groups per number average molecular weight is shown in Table 1. Note that in Comparative Example 1 and Reference Example 1, since they do not have a terminal structure derived from the phenol compound X, the number of terminal reactive groups per number average molecular weight was not calculated.

As shown in Table 1, it was shown that by using the phenol (X) having a predetermined functional group in at least para and ortho positions as shown in Formula (1) as a raw material phenol of the polyphenylene ether having a branched structure, a polyphenylene ether with a further reduced molecular weight can be obtained, and an increase in molecular weight is suppressed.

On the other hand, although the polyphenylene ether of Reference Example 1 had the same reaction time, the polyphenylene ether of Reference Example 1 was a polyphenylene ether having a higher molecular weight as compared with the polyphenylene ethers of Examples 1 and 2.

As shown in Table 1, according to Example 1 and Example 2, it is possible to introduce many reactive groups (allyl groups) at the terminal portion.

Note that in Comparative Example 1 and Reference Example 1, since the phenol compound X was not used, the number of terminal reactive groups per number average molecular weight was not calculated.

TABLE 1

| | | | | Comparative | Reference |
|---|---|---|---|---|---|
| | | Example 1 | Example 2 | Example 1 | Example 1 |
| A | 2,6-Dimethylphenol (g) | 34.51 | 8.15 | 16.23 | 40.20 |
| B | 2-Allylphenol (g) | 4.71 | 0.91 | 2.38 | 4.88 |
| C | 4-Allyl-2,6-dimethylphenol (g) | 5.70 | — | — | — |
| | 2-Allyl-4,6-dimethylphenol (g) | — | 1.07 | — | — |
| | 2,4,6-Trimethylphenol (g) | — | — | 3.62 | — |

| A: B:C (mol) | 8:1:1 | 8:1:1 | 7.5:1.0:1.5 | 9:1:0 |
|---|---|---|---|---|
| | 100 mL | | 500 mL | |
| Reaction vessel | two-necked flask | | separable flask | |
| Toluene (g) | 286.3 | 58.61 | 168 | 286.11 |
| TMEDA (g) | 1.06 | 0.217 | 0.45 | 1.01 |
| Cu/TMEDA (g) | 1.04 | 0.226 | 0.50 | 1.04 |
| Stirring speed (rpm) | 200 | 350 | 200 | 200 |
| Air flow rate (mL/min) | 150 | 30 | 75 | 150 |
| Reaction temperature (°C.) | 40 | 40 | 40 | 40 |
| Reaction time (h) | 15 | 15 | 15 | 15 |
| Mₙ | 7,700 | 6,000 | 6,300 | 11,700 |
| M_{w} | 16,000 | 11,000 | 16,200 | 26,100 |
| Number of terminal reactive | 3.5 | 3.4 | — | — |
| groups (per Mn) | | | | |

### <<Evaluation>>

The polyphenylene ethers according to Examples 1 and 2 and the polyphenylene ether according to Comparative Example 1 were evaluated.

### <Production of Cured Film>

100 parts by mass of each polyphenylene ether, 50 parts by mass of a crosslinking curing agent (product name “TAIC”, manufactured by Mitsubishi Chemical Corporation), 5 parts by mass of a peroxide (product name “PERBUTYL P40”, manufactured by NOF Corporation), and 350 parts by mass of cyclohexanone (solvent) were mixed to prepare a resin composition.

Each resin composition was applied onto a shine surface of a copper foil having a thickness of 18 μm so that the film thickness after drying was about 20 μm, and dried in a hot air circulating drying furnace at 90° C. for 30 minutes. Subsequently, the copper foil was cured in an inert oven under the condition of 200° C. and 1 h, and then etched to obtain a single cured film (measurement sample).

Comparative Example 1 was a polyphenylene ether capable of suppressing an increase in molecular weight to the same extent as in Examples 1 and 2, but a large number of cracks occurred in the cured product at the time point after curing, and a single cured film could not be obtained. On the other hand, in each of Examples 1 and 2, the cured product was not cracked, and a single cured film could be obtained, and thus it was confirmed that the mechanical strength of the cured product was improved as compared with Comparative Example 1. Note that since a single cured film could not be obtained in Comparative Example 1, the following evaluation was not performed.

### <Dielectric Constant>

### (Measurement Method)

The measurement sample was cut into a length of 80 mm and a width of 45 mm to obtain a test piece, and the relative dielectric constant Dk was measured by a split post dielectric resonator (SPDR) method. As a measuring instrument, a vector network analyzer E5071C manufactured by Keysight Technologies LLC, an SPDR resonator, and a calculation program manufactured by QWED were used. The conditions were a frequency of 10 GHz and a measurement temperature of 25° C.

### (Measurement Results)

The Dk of the cured product obtained using the polyphenylene ether of Example 1 was 2.4.

The Dk of the cured product obtained using the polyphenylene ether of Example 2 was 2.7.

From the above results, it was shown that excellent low-dielectric characteristics were exhibited even when the phenol compound (X) (phenol having a predetermined functional group in at least para and ortho positions) was used as a raw material phenol of the polyphenylene ether having a branched structure.

### <Tensile Characteristics>

### (Measurement Method)

The measurement sample was cut into a length of 8 cm and a width of 0.5 cm, and the elongation at break (tensile elongation at break) was measured under the following conditions. Note that the elastic modulus was determined from the slope of strain when the stress in the obtained stress-strain diagram was from 5 MPa to 10 MPa.

### [Measurement Conditions]

Tester: Tensile tester EZ-SX (manufactured by SHIMADZU CORPORATION)
Inter-chuck distance: 50 mm
Test rate: 1 mm/min
Elongation calculation: (Tensile movement amount/Inter-chuck distance)×100

### (Measurement Results)

The elastic modulus of the cured product obtained using the polyphenylene ether of Example 1 was 2.4 GPa and the elongation at break thereof was 3.4%.

The elastic modulus of the cured product obtained using the polyphenylene ether of Example 2 was 3.9 GPa and the elongation at break thereof was 1.4%.

From the above results, it was shown that by using the phenol compound (X) (the phenol having a predetermined functional group in at least the para and ortho positions) as a raw material phenol of the polyphenylene ether having a branched structure, an excellent mechanical strength is exhibited while the molecular weight is controlled, and particularly, by using the phenol having a predetermined hydrocarbon group in the para position, the elongation at break is excellent, and by using the phenol having a predetermined hydrocarbon group in the ortho position, the elastic modulus is excellent.

### INDUSTRIAL APPLICABILITY

The polyphenylene ether according to the present invention has low-dielectric characteristics and excellent solvent solubility, is easily controlled in molecular weight, and is suitable for mass production. Therefore, the polyphenylene ether according to the present invention is preferably used for producing a cured product constituting an insulating material or the like in electronic components such as millimeter-wave radars and the like for high-capacity and high-speed communication typified by the 5th generation communication system (5G) or advanced driver assistance system (ADAS) of automobiles.

### CROSS-REFERENCE TO RELATED APPLICATIONS

The present application claims priority based on Japanese Patent Application No. 2023-107451 filed with the Japan Patent Office on Jun. 29, 2023, the entire disclosure of which is entirely incorporated herein by reference.

1. A polyphenylene ether obtained from raw material phenols, wherein
the raw material phenols include a first phenol having a hydrogen atom at the ortho position and the para position and a second phenol represented by the formula (1): 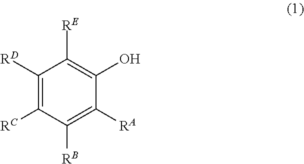
wherein, in formula (1), R^{A}, R^{C}, and R^{E} are each independently a functional group having 1 to 10 carbon atoms, R^{B} and R^{D} are each independently hydrogen or a functional group having 1 to 10 carbon atoms, and one or more of R^{A} to R^{E} are a functional group containing an unsaturated carbon bond.

2. The polyphenylene ether according to claim 1, wherein the second phenol is a compound represented by the formula (2) or (3)

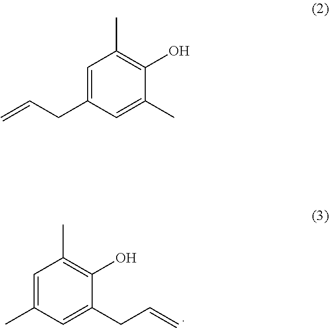

3. A curable composition comprising the polyphenylene ether according to claim 1.

4. A dry film or prepreg obtained by applying or impregnating the curable composition according to claim 3 to a base material.

5. A cured product obtained by curing the curable composition according to claim 3.

6. A laminate comprising the cured product according to claim 5.

7. An electronic component comprising the cured product according to claim 5.

8. A curable composition comprising the polyphenylene ether according to claim 2.

9. A dry film or prepreg obtained by applying or impregnating the curable composition according to claim 8 to a base material.

10. A cured product obtained by curing the curable composition according to claim 8.

11. A laminate comprising the cured product according to claim 10.

12. An electronic component comprising the cured product according to claim 10.
